(19) United States
(12) Patent Application Publication
(10) Pub. No.: US 2019/0279990 A1
(43) Pub. Date: Sep. 12, 2019

(54) BITCELL LAYOUT FOR A TWO-PORT SRAM CELL EMPLOYING VERTICAL-TRANSPORT FIELD-EFFECT TRANSISTORS

(71) Applicant: GLOBALFOUNDRIES Inc., Grand Cayman (KY)

(72) Inventors: Bipul C. Paul, Mechanicville, NY (US); Joseph Versaggi, Galway, NY (US); Steven Bentley, Menands, NY (US)

(21) Appl. No.: 15/917,027

(22) Filed: Mar. 9, 2018

(51) Int. Cl. H01L 27/11; G11C 11/412; G11C 11/419; H01L 51/05; H01L 29/78; H01L 29/06; H01L 27/28

(52) U.S. Cl. CPC H01L 27/11; G11C 11/412; G11C 11/419; H01L 27/283; H01L 29/7827; H01L 29/0692; H01L 51/057

(57) ABSTRACT

Structures for a bitcell of a two-port static random access memory (SRAM) and methods for forming a structure for a bitcell of a two-port SRAM. A storage element of the SRAM includes a first pull-up (PU) vertical-transport field-effect transistor (VTFET) with a fin, a first pull-down (PD) VTFET with a fin that is aligned in a first row with the fin of the first PU VTFET, a second PU VTFET with a fin, and a second PD VTFET with a fin that is aligned in a second row with the fin of the second PU VTFET. The structure further includes a read port coupled with the storage element. The read port includes a read port pull-down (RPD) VTFET with a fin and a read port access (RPG) VTFET with a fin that is aligned in a third row with the fin of the RPG VTFET.

### BACKGROUND

The present invention relates to semiconductor device fabrication and integrated circuits and, more specifically, to structures for a two-port static random access memory bitcell and methods for forming a two-port static random access memory bitcell.

Static random access memory (SRAM) may be used, for example, to temporarily store data in a computer system. When continuously powered, SRAM retains its memory state without the need for data refresh operations. An SRAM device includes an array of bitcells and each bitcell retains a single bit of data during operation. Each SRAM bitcell may include a pair of cross-coupled inverters and a pair of access transistors connecting the inverters to complementary bit lines. The two access transistors are controlled by word lines, which are used to select each individual SRAM cell for read or write operations.

A two-port SRAM is implemented with an additional pair of transistors that allows multiple read or write operations to occur at, or nearly at, the same time. In a typical 2CPP-wide two-port SRAM bitcell, the additional access transistor and pull-down transistor of the read port are both placed at one side of the bitcell. This layout for the access transistor and pull-down transistor contributes to increasing the cell height and, thereby, increases the aspect ratio of the two-port SRAM. The increase in the aspect ratio impacts the performance and the yield due to the increase in the word line resistance. Consequently, the size of a block in the circuit design may be limited by restricting the maximum number of bits/wordline.

### SUMMARY

In an embodiment, a structure is provided for a bitcell of a two-port static random-access memory. The structure includes a storage element including a first pull-up (PU) vertical-transport field-effect transistor (VTFET) with a fin, a first pull-down (PD) vertical-transport field-effect transistor (VTFET) with a fin that is aligned in a first row with the fin of the first PU VTFET, a second pull-up (PU) vertical-transport field-effect transistor (VTFET) with a fin, and a second pull-down (PD) vertical-transport field-effect transistor (VTFET) with a fin that is aligned in a second row with the fin of the second PU VTFET. The structure further includes a read port coupled with the storage element. The read port includes a read port access (RPG) vertical-transport field-effect transistor (VTFET) with a fin and a read port pull-down (RPD) vertical-transport field-effect transistor (VTFET) with a fin that is aligned in a third row with the fin of the RPG VTFET.

In an embodiment, a method of forming a structure for a bitcell of a two-port static random-access memory is provided. The method includes forming a first pull-up (PU) vertical-transport field-effect transistor (VTFET) and a first pull-down (PD) vertical-transport field-effect transistor (VTFET) of a storage element that include respective first fins aligned in a first row, and forming a second pull-up (PU) vertical-transport field-effect transistor and a second pull-down (PD) vertical-transport field-effect transistor (VTFET) of the storage element that include respective second fins aligned in a second row. The method further includes forming a read port access (RPG) vertical-transport field-effect transistor (VTFET) and a read port pull-down (RPD) vertical-transport field-effect transistor (VTFET) of a read port that include respective third fins aligned in a third row.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention.

FIGS. 1-3 are top views showing a structure at successive fabrication stages of a processing method in accordance with embodiments of the invention.

FIG. 4 is a cross-sectional view taken generally along line 4-4 in FIG. 3.

FIG. 4A is a cross-sectional view taken generally along line 4A-4A in FIG. 3.

FIG. 4B is a cross-sectional view taken generally along line 4B-4B in FIG. 3.

FIGS. 5, 5A, 5B are respective cross-sectional views of the structure at a fabrication stage of the processing method subsequent to FIGS. 4, 4A, 4B.

FIG. 6 is a top view of the structure at a fabrication stage of the processing method subsequent to FIGS. 5, 5A, 5B.

FIG. 7 is a top view similar to FIG. 6 showing a structure formed by a processing method in accordance with alternative embodiments of the invention.

### DETAILED DESCRIPTION

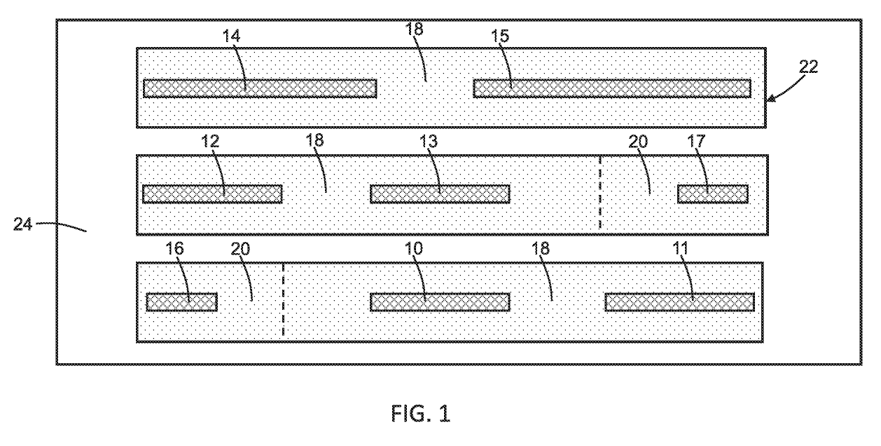

With reference to FIG. 1 and in accordance with embodiments of the invention, a plurality of fins 10-15 each project in a vertical direction from one of multiple bottom source/drain regions 18 and fins 16, 17 each project in a vertical direction from one of multiple bottom source/drain regions 20. As used herein, the term “source/drain region” connotes a doped region of semiconductor material that can function as either a source or a drain of a vertical-transport field-effect transistor. The bottom source/drain regions 18, 20 are formed at a top surface of a substrate 22. The bottom source/drain regions 18 may be formed by a process that results in the replacement of the semiconductor material of the substrate 22 with doped epitaxial semiconductor material of a given conductivity type, and the bottom source/drain regions 20 may be formed by a process that results in the replacement of the semiconductor material of the substrate 22 with doped epitaxial semiconductor material of a given conductivity type opposite from the bottom source drain regions 18.

Shallow trench isolation regions 24 formed in the substrate 22 operate to electrically isolate the different bottom source/drain regions 18, 20 from each other. The shallow trench isolation regions 24 may be formed with a lithography and etching process to define trenches in the substrate 22, and filling the trenches with a dielectric material, such as an oxide of silicon (e.g., silicon dioxide (SiO₂)) or other electrical insulator, deposited by chemical vapor deposition (CVD).

The fins 10-17 may be formed from semiconductor material, such as the semiconductor material of the substrate 22, patterned using photolithography and etching processes, such as a sidewall imaging transfer (SIT) process or self-aligned double patterning (SADP), and cut into given lengths in the layout. The fins 10-17 are used to construct different single-fin vertical-transport field-effect transistors (VTFETs) of a two-port static random access memory (SRAM) as described hereinbelow. Fins 10 and 11 are aligned in a row with fin 16. Fin 10 may be used to form a pull-down (PD) VTFET, fin 11 may be used to form a pass-gate (PG) VTFET for read or write operations, and fin 16 may be used to form a pull-up (PU) VTFET. Fins 12 and 13 are aligned in a row with fin 17. Fin 12 may be used to form a pass-gate (PG) VTFET for read or write operations, fin 13 may be used to form a pull-down (PD) VTFET, and fin 17 may be used to form a pull-up (PU) VTFET. Fin 14 is aligned in a row with fin 15. Fin 14 may be used to form a read port access (RPG) VTFET and fin 15 may be used to form a read port pull-down (RPD) VTFET. In an embodiment, a two-port SRAM formed using the fins 10-17 may have a three contacted (poly) pitch (3CPP) structure relating to the arrangement of the subsequently-formed gates in association with the fins 10-17. The different rows of fins 10, 11, 16, fins 12, 13, 17, and fins 14, 15 are arranged parallel to each other in the 3CPP structure.

In connection with the formation of n-type vertical-transport field-effect transistors, the bottom source/drain regions 18 may be include an n-type dopant from Group V of the Periodic Table (e.g., phosphorus (P) and/or arsenic (As)) that provides n-type electrical conductivity. In connection with the formation of p-type vertical-transport field-effect transistors, the bottom source/drain regions 20 may include a p-type dopant from Group III of the Periodic Table (e.g., boron (B), aluminum (Al), gallium (Ga), and/or indium (In)) that provides p-type electrical conductivity.

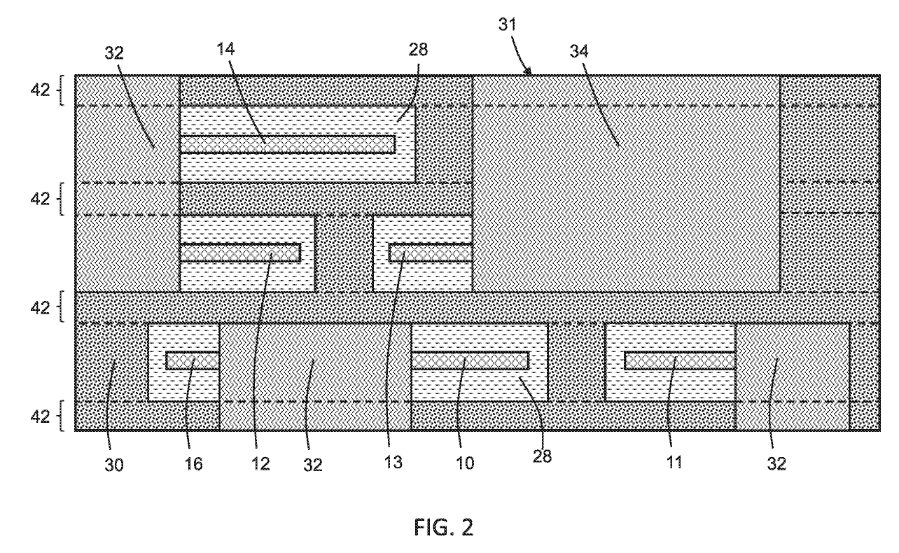

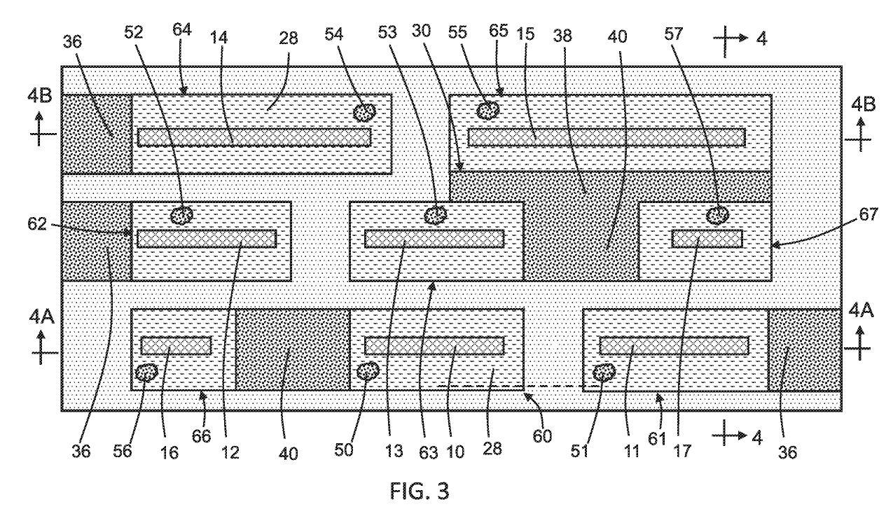

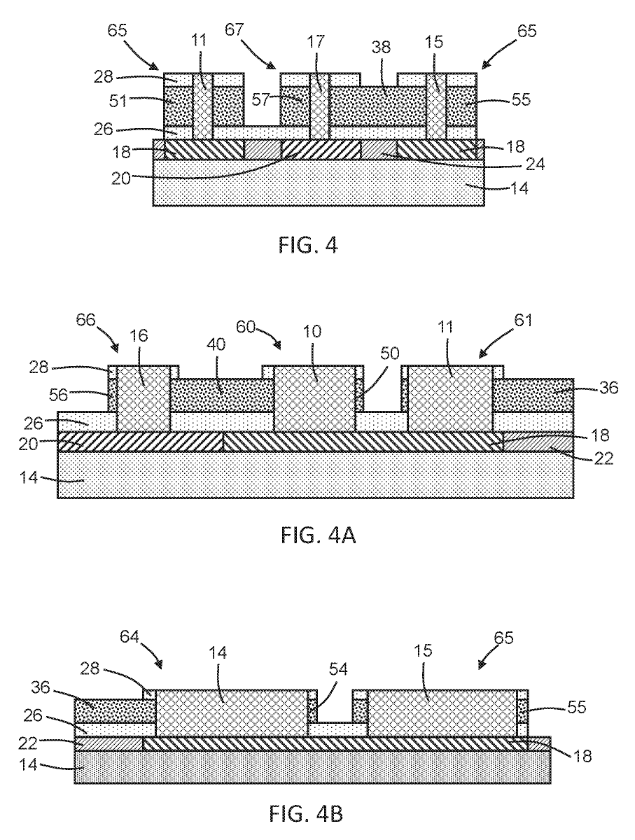

With reference to FIG. 2 in which like reference numerals refer to like features in FIG. 1 and at a subsequent fabrication stage, a bottom spacer layer 26 (FIGS. 4, 4A, 4B) is arranged over the bottom source/drain regions 16, 18 and shallow trench isolation regions 24. The bottom spacer layer 26 may be composed of a dielectric material, such as silicon nitride (Si₃N₄), that is deposited by a directional deposition technique, such as high-density plasma (HDP) deposition or gas cluster ion beam (GCIB) deposition. The fins 10-17 extend in the vertical direction through the thickness of a respective section of the bottom spacer layer 26 and project to a given height above the bottom spacer layer 26.

A gate stack 30 is arranged over the bottom spacer layer 26 and may surround all sides of each of the fins 10-17 in a gate-all-around (GAA) arrangement. The gate stack 30 may include one or more conformal barrier metal layers and/or work function metal layers, such as layers composed of titanium aluminum carbide (TiAlC) and/or titanium nitride (TiN), and a metal gate fill layer composed of a conductor, such as tungsten (W). The layers of gate stack 30 may be serially deposited by, for example, atomic layer deposition (ALD), physical vapor deposition (PVD), or chemical vapor deposition (CVD), over the fins 10-17 and may be etched back by chamfering to a given thickness. A gate dielectric layer (not shown) is arranged between the gate stack 30 and the fins 10-17 and bottom spacer layer 26. The gate dielectric layer may be composed of a high-k dielectric material, such as a hafnium-based dielectric material like hafnium oxide (HfO₂) deposited by atomic layer deposition (ALD).

Sections of a top spacer layer 28 are arranged about the fins 10-17 and over the gate stack 30. The top spacer layer 28 may be composed of a dielectric material, such as silicon nitride (Si₃N₄), that is deposited by a directional deposition technique, such as high-density plasma (HDP) deposition or gas cluster ion beam (GCIB) deposition. The fins 10-17 extend in the vertical direction through the thickness of the top spacer layer 28 and may project a given distance above the top spacer layer 28.

With reference to FIG. 3 in which like reference numerals refer to like features in FIG. 2 and at a subsequent fabrication stage, an etch mask, generally indicated by reference numeral 31, is formed by lithography over sections of the gate stack 30. The etch mask 31 may be comprised of a layer of a light-sensitive material, such as an organic photoresist, applied by a spin coating process, pre-baked, exposed to light projected through a photomask, baked after exposure, and developed with a chemical developer. The etch mask 31 may also include an anti-reflective coating and a spin-on hardmask, such as an organic planarization layer (OPL), that are patterned along with the patterned photoresist.

The etch mask 31 is a composite etch mask in which the light-sensitive material is exposed to provide a pattern that, after developing, includes sections 32, 34 of the light-sensitive material covering underlying sections of the gate stack 30. The sections 32, following etching, are used to provide gate extensions contacting the gates from which they respectively extend and gate extensions that provide cross-couplings between the gates of each PU VTFET and PD VTFET pair. The section 34 of the etch mask 31 covers an underlying section of the gate stack 30 that, following etching, is used to provide a connection between the gate of the RPD VTFET associated with fin 15 and the gate of the adjacent PU VTFET associated with fin 17. The discrete sections 32 and 34 of the etch mask 31 are disconnected and spaced from each other.

Before developing, the etch mask 31 is modified to add another component in which the light-sensitive material is exposed to provide a pattern that, after developing, introduces cuts 42 as a set of parallel openings in the etch mask 31. The cuts 42 introduce longitudinal cuts into the gate stack 30 that disconnect the gates of most of the VTFETs, as well as disconnect the gates of the two-port SRAM bitcell from the gates of surrounding two-port SRAM bitcells. An exception to the disconnection of the gates of the VTFETs is that one of the cuts 42 of the etch mask 31 is interrupted across the section 34 of the etch mask 31 so as to preserve the integrity of the section 34 between the gate of the RPD VTFET associated with fin 15 and the gate of the adjacent PU VTFET associated with fin 17 in the middle row.

The etch mask 31 is overlaid on the sections of the top spacer layer 28 respectively associated with the fins 10-17. These sections of the top spacer layer 28 mask underlying equal-size sections of the gate stack 30 respectively associated with the fins 10-17, which form the gates of the VTFETs and are protected and preserved during the etching process that patterns the gate stack 30.

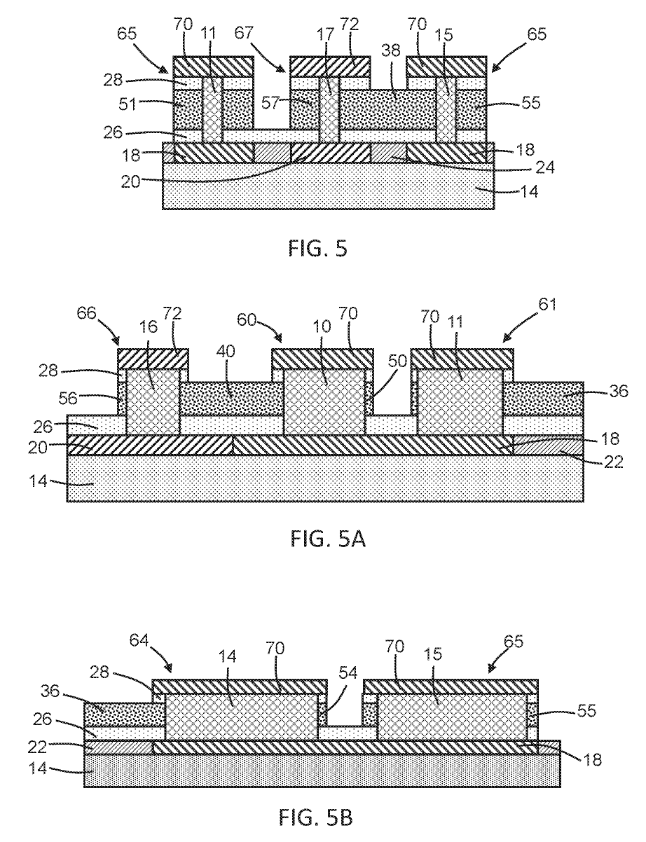

With reference to FIGS. 4, 5, 5A, 5B in which like reference numerals refer to like features in FIG. 3 and at a subsequent fabrication stage, the gate stack 30 is patterned with an etching process that removes the gate stack 30 over areas that are not covered by the sections 32, 34 of the etch mask 31 or by a section of the top spacer layer 28. Areas of the bottom spacer layer 26 are exposed by the patterning of the gate stack 30. The patterned gate stack 30 includes sections 36 representing gate extensions that are used to provide gate contacts through vertical interconnects, a section 38 representing a gate extension of the gate of the RPD VTFET that provides an integral and monolithic connection with the gates of the adjacent PU VTFET and PD VTFET, and sections 40 that are used to provide cross-couplings between the gates and bottom source/drain regions 18, 20 of each PU VTFET and PD VTFET pair. These preserved sections 36, 38, 40 are covered by the sections 32, 34 of the etch mask 31 during the etching process.

The patterned gate stack 30 includes a gate 50 that is wrapped about and surrounds the fin 10 that is used to form a pull-down (PD) vertical-transport field-effect transistor (VTFET) 60, a gate 51 that is wrapped about and surrounds the fin 11 may be used to form a pass-gate (PG) VTFET 61, and a gate 56 that is wrapped about and surrounds the fin 16 may be used to form a pull-up (PU) VTFET 66. The patterned gate stack 30 further includes a gate 52 that is wrapped about and surrounds the fin 12 used to form a pass-gate (PG) VTFET 62, a gate 53 that is wrapped about and surrounds the fin 13 used to form a pull-down (PD) VTFET 63, and gate 57 that is wrapped about and surrounds the fin 17 may be used to form a pull-up (PU) VTFET 67. The patterned gate stack 30 further includes a gate 54 that is wrapped about and surrounds the fin 14 used to form read port access (RPG) VTFET 64, and a gate 55 that is wrapped about and surrounds the fin 15 may be used to form a read port pull-down (RPD) VTFET 65. In an embodiment, a two-port SRAM formed using the fins 10-17 may have a three contacted (poly) pitch (3CPP) structure relating to the arrangement of the subsequently-formed gates in association with the fins 10-17. The gates 50-57 are covered by the respective sections of the top spacer layer 28. The gate 57 of the PU VTFET 67 is integral with the section 38 of the gate stack 30, and the gate 55 of the RPD VTFET 65 is also integral with the section 38 of the gate stack 30 such that the gate 55, the gate 57, and the section 38 are a single monolithic piece of the gate stack 30.

With reference to FIGS. 5, 5A, 5B in which like reference numerals refer to like features in FIGS. 4, 4A, 4B and at a subsequent fabrication stage, top source/drain regions 70 and top source/drain regions 72 are formed on upper section of the fins 11-17 and over the top spacer layer 28. The top source/drain regions 70 may be composed of semiconductor material that is doped to have the same conductivity type as the bottom source/drain regions 18, and the top source/drain regions 72 may be composed of semiconductor material that is doped to have the same conductivity type as the bottom source/drain region 20. If the bottom source/drain regions 18 are n-type, then the top source/drain regions 70 may be sections of semiconductor material formed by an epitaxial growth process with in-situ doping, and may contain an n-type dopant from Group V of the Periodic Table (e.g., phosphorus (P) and/or arsenic (As)) that provides n-type electrical conductivity. If the bottom source/drain regions 20 are p-type, then the top source/drain regions 72 may be sections of semiconductor material formed by an epitaxial growth process with in-situ doping, and may include a concentration of a p-type dopant from Group III of the Periodic Table (e.g., boron (B), aluminum (Al), gallium (Ga), and/or indium (In)) that provides p-type electrical conductivity. In an embodiment, the top source/drain regions 70, 72 may be formed by respective selective epitaxial growth (SEG) processes in which the constituent semiconductor material nucleates for epitaxial growth on semiconductor surfaces (e.g., fins 10-17), but does not nucleate for epitaxial growth from insulator surfaces.

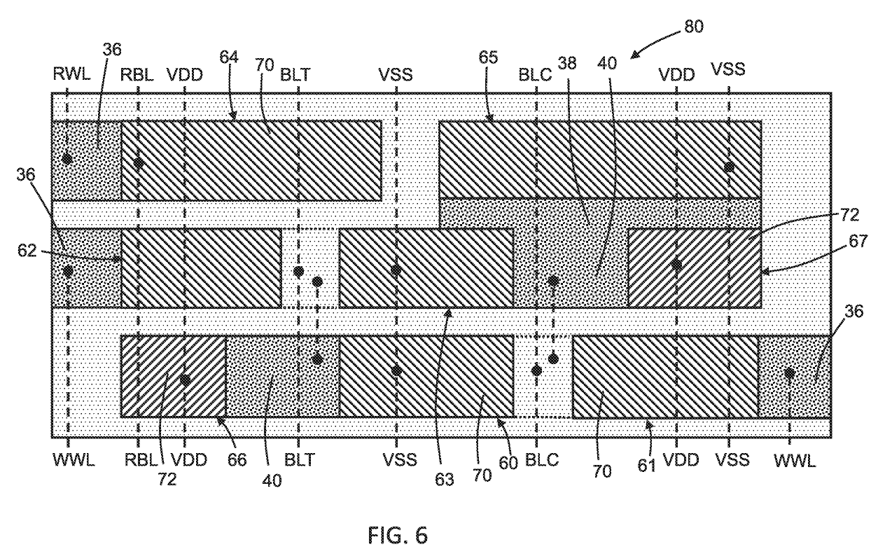

With reference to FIG. 6 in which like reference numerals refer to like features in FIGS. 5, 5A, 5B and at a subsequent fabrication stage, an interconnect structure is formed by middle-of-line (MOL) and back-end-of-line (BEOL) processing to provide connections to the structure for the two-port SRAM 80 including the VFETs 60-67 after the VFETs 60-67 that are formed by front-end-of-line (FEOL) processing. The top source/drain regions 70, 72 are used for signal and power routing in the two-port SRAM 80, and the bottom source/drain regions 18, 20 are used for cross-couple contacts in the two-port SRAM 80. The two-port SRAM 80 includes six VTFETs 60-65 of one conductivity type (e.g., n-type) and two VTFETs 66 and 67 of the complementary conductivity type (e.g., p-type).

The storage element of the two-port SRAM 80 includes the PD VTFET 60, the PU VTFET 66 that forms an inverter with the PD VTFET 60, the PD VTFET 63, and the PU VTFET 67 that forms an inverter with the PD VTFET 63. These inverters are cross-coupled using the abutting bottom source/drain regions 18, 20 of the VTFETS 60, 66 and the gates 53, 57 of the VTFETs 63, 67, and using the abutting bottom source/drain regions 18, 20 of the VTFETS 63, 67 and the gates 50, 56 of the VTFETs 60, 66. A write word line (WWL) is connected with the gate 51 of the PG VTFET 61 and with the gate 52 of the PG VTFET 62. A true bit line (BLT) is connected with the top source/drain region 70 of the PG VTFET 63, which is the drain region of the PG VTFET 63 in the representative embodiment. A complementary bit line (BLC) is connected with the top source/drain region 70 of the PG VTFET 61, which is the drain region of the PG VTFET 61 in the representative embodiment. The top source/drain region 72 of the PU VTFET 66 and the top source/drain region 72 of the PU VTFETs 67, which are source regions in the representative embodiment, are connect with a positive supply voltage (V_{DD}) line. The top source/drain region 70 of the PD VTFET 60 and the top source/drain region 70 of the PD VTFET 63, which are source regions in the representative embodiment, are connected with a ground power supply (V_{SS}) line. The connections are diagrammatically indicated in FIG. 6 by the filled circles.

The read port of the two-port SRAM 80 includes the RPG VTFET 64 and the RPD VTFET 65. A read word line (RWL) is connected with the gate 54 of the RPG VTFET 64. A read bit line (RBL) represents a data access line that is connected with the top source/drain region 70 of the RPG VTFET 64, which is the drain of the RPG VTFET 64 in the representative embodiment. The top source/drain region 70 of the RPD VTFET 65, which is a source region in the representative embodiment, is tied to the ground power supply (V_{SS}) line. The RPG VTFET 64 and the RPD VTFET 65 of the read port share the same bottom source/drain region 18 in common such that their drain regions are coupled together to provide an internal node connection.

The abutment of the bottom source/drain region 18 of the PD VTFET 60 with the bottom source/drain region 20 of the PU VTFET 66 along a vertical interface couples their respective drains together in the representative embodiment. Similarly, the abutment of the bottom source/drain region 18 of the PD VTFET 63 with the bottom source/drain region 20 of the PU VTFET 67 along a vertical interface couples their respective drains together in the representative embodiment.

The sections 36 of the patterned gate stack 30 respectively represent a gate extension to the gate 51 of the PG VTFET 61, a gate extension to the gate 52 of the PG VTFET 62, and a gate extension to the gate 54 of the RPG VTFET 64. One of the sections 38 of the patterned gate stack 30 couples the gate 56 of the PU VTFET 66 with the gate 50 of the PD VTFET 60. The other section 38 of the patterned gate stack 30 couples the gate 57 of the PU VTFET 67 with the gate 53 of the PD VTFET 63. The section 40 of the patterned gate stack 30 couples the gate 55 of the RPD VTFET 65 with the gate 57 of the PU VTFET 67.

The PU VTFET 66 is arranged at a side or end of the row that includes the fins 10, 11, and fin 16. The PU VTFET 67 is arranged at a side or end of the row that includes the fins 12, 13, and fin 17, and is arranged at an opposite end of the rows from the PU VTFET 66.

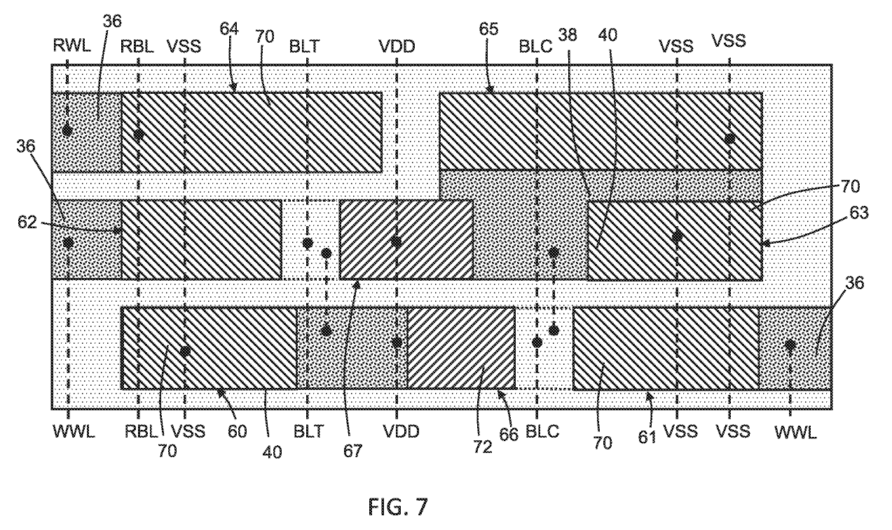

With reference to FIG. 7 in which like reference numerals refer to like features in FIG. 6 and in accordance with alternative embodiments of the invention, the location of the PU VTFET 66 in the SRAM portion of the two-port SRAM 80 may be swapped with the location of the PD VTFET 60 in the storage element of the SRAM portion of the two-port SRAM 80, and the location of the PU VTFET 67 in the SRAM portion of the two-port SRAM 80 may be swapped with the location of the PD VTFET 63 in the storage element of the SRAM portion of the two-port SRAM 80. The relocated PU VTFETs 66 and 67 are centrally arranged in the storage element of the SRAM portion of the two-port SRAM 80. This transistor rearrangement will necessitate swapping of V_{SS} and V_{DD} lines in the interconnect structure as shown in FIG. 7.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

References herein to terms such as “vertical”, “horizontal”, “lateral”, etc. are made by way of example, and not by way of limitation, to establish a frame of reference. Terms such as “horizontal” and “lateral” refer to a direction in a plane parallel to a top surface of a semiconductor substrate, regardless of its actual three-dimensional spatial orientation. Terms such as “vertical” and “normal” refer to a direction perpendicular to the “horizontal” and “lateral” direction. Terms such as “above” and “below” indicate positioning of elements or structures relative to each other and/or to the top surface of the semiconductor substrate as opposed to relative elevation.

A feature “connected” or “coupled” to or with another element may be directly connected or coupled to the other element or, instead, one or more intervening elements may be present. A feature may be “directly connected” or “directly coupled” to another element if intervening elements are absent. A feature may be “indirectly connected” or “indirectly coupled” to another element if at least one intervening element is present.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure for a bitcell of a two-port static random-access memory, the structure comprising:
a storage element including a first pull-up (PU) vertical-transport field-effect transistor (VTFET) with a fin, a first pull-down (PD) vertical-transport field-effect transistor (VTFET) with a fin that is aligned in a first row with the fin of the first PU VTFET, a second pull-up (PU) vertical-transport field-effect transistor (VTFET) with a fin, and a second pull-down (PD) vertical-transport field-effect transistor (VTFET) with a fin that is aligned in a second row with the fin of the second PU VTFET; and
a read port coupled with the storage element, the read port including a read port access (RPG) vertical-transport field-effect transistor (VTFET) with a fin and a read port pull-down (RPD) vertical-transport field-effect transistor (VTFET) with a fin that is aligned in a third row with the fin of the RPG VTFET.

2. The structure of claim 1 wherein the first row, the second row, and the third row are spaced apart from each other, the first row is arranged parallel with the second row, and the third row is arranged parallel with the second row.

3. The structure of claim 2 wherein the second row is arranged between the first row and the third row.

4. The structure of claim 2 wherein the first PU VTFET of the storage element is arranged at an end of the first row, and the second PU VTFET of the storage element is arranged at an end of the second row that is opposite from the end of the first row.

5. The structure of claim 2 wherein the first PD VTFET of the storage element is arranged at an end of the first row, and the second PD VTFET of the storage element is arranged at an end of the second row that is opposite from the end of the first row.

6. The structure of claim 1 wherein the RPG VTFET of the read port and the RPD VTFET of the read port include a bottom source/drain region, and the fin of the RPG VTFET of the read port and the fin of the RPD VTFET of the read port each project vertically from the bottom source/drain region.

7. The structure of claim 6 wherein the RPG VTFET of the read port includes a first top source/drain region, the RPD VTFET of the read port includes a second top source/drain region, and further comprising:
a data access line coupled with the first top source/drain region; and
a ground power supply line coupled with the second top source/drain region.

8. The structure of claim 1 wherein the first PU VTFET of the storage element has a first bottom source/drain region of a first conductivity type, the first PD VTFET of the storage element has a first bottom source/drain region of a second conductivity type, and the first bottom source/drain region of the first PU VTFET of the storage element has a directly contacting relationship with the first bottom source/drain region of the first PD VTFET of the storage element.

9. The structure of claim 8 wherein the second PU VTFET of the storage element has a first gate and the second PD VTFET of the storage element has a second gate coupled with the first gate, and the first bottom source/drain region of the first PU VTFET of the storage element and the first bottom source/drain region of the first PD VTFET of the storage element are coupled with the first gate and the second gate.

10. The structure of claim 8 wherein the second PU VTFET of the storage element has a second bottom source/drain region of the second conductivity type, the second PD VTFET of the storage element has a second bottom source/drain region of the second conductivity type, and the second bottom source/drain region of the second PU VTFET of the storage element has a directly contacting relationship with the second bottom source/drain region of the second PD VTFET of the storage element.

11. The structure of claim 1 wherein the RPG VTFET of the read port includes a first top source/drain region, the RPD VTFET of the read port include a second top source/drain region, and further comprising:
a data access line coupled with the first top source/drain region; and
a ground power supply line coupled with the second top source/drain region.

12. The structure of claim 1 wherein the first PU VTFET of the storage element has a gate, the second PD VTFET of the storage element has a gate coupled with the gate of the first PU VTFET of the storage element, and the RPD VTFET of the read port has a gate that is directly coupled with the gate of the first PU VTFET of the storage element and with the gate of the first PD VTFET of the storage element.

13. The structure of claim 12 wherein the gate of the RPD VTFET of the read port, the gate of the first PU VTFET of the storage element, and the gate of the first PD VTFET of the storage element comprise a plurality of sections of a gate stack that are monolithic.

14. The structure of claim 12 wherein the third row is arranged parallel with the second row, and the gate of the RPD VTFET of the read port is directly coupled with the gate of the first PU VTFET of the storage element and the gate of the first PD VTFET of the storage element by a gate extension spanning across a space between the second row and the third row.

15. A method of forming a structure for a bitcell of a two-port static random-access memory, the method comprising:
forming a first pull-up (PU) vertical-transport field-effect transistor (VTFET) and a first pull-down (PD) vertical-transport field-effect transistor (VTFET) of a storage element that include respective first fins aligned in a first row;
forming a second pull-up (PU) vertical-transport field-effect transistor and a second pull-down (PD) vertical-transport field-effect transistor (VTFET) of the storage element that include respective second fins aligned in a second row; and
forming a read port access (RPG) vertical-transport field-effect transistor (VTFET) and a read port pull-down (RPD) vertical-transport field-effect transistor (VTFET) of a read port that include respective third fins aligned in a third row.

16. The method of claim 15 wherein the first row, the second row, and the third row are spaced apart from each other, the first row is arranged parallel with the second row, the third row is arranged parallel with the second row, and the first row is arranged between the second row and the third row.

17. The method of claim 15 further comprising:
forming a gate stack that surrounds the first fins, the second fins, and the third fins; and
patterning the gate stack to form a gate of the RPD VTFET of the read port, a gate of the first PD VTFET of the storage element, a gate of the first PU VTFET of the storage element, and a gate extension that connects the gate of the RPD VTFET of the read port with the gate of the first PD VTFET of the storage element and the gate of the first PU VTFET of the storage element.

18. The method of claim 17 wherein the first row is arranged parallel with the second row, the third row is arranged parallel with the second row, and the first row is arranged between the second row and the third row.

19. The method of claim 18 wherein the first PU VTFET of the storage element is arranged at an end of the first row, and the second PU VTFET of the storage element is arranged at an end of the second row that is opposite from the end of the first row.

20. The method of claim 15 further comprising:
forming a bottom source/drain region from which the third fins of the RPD VTFET of the read port and the RPG VTFET of the read port each project vertically.
